(19) United States
(12) Patent Application Publication
(10) Pub. No.: US 2016/0116527 A1
(43) Pub. Date: Apr. 28, 2016

(54) STOCHASTIC AND TOPOLOGICALLY AWARE ELECTROMIGRATION ANALYSIS METHODOLOGY

(71) Applicant: QUALCOMM Incorporated, San Diego, CA (US)

(72) Inventor: Palkesh Jain, Bangalore (IN)

(21) Appl. No.: 14/865,339

(22) Filed: Sep. 25, 2015

(30) Foreign Application Priority Data
Oct. 27, 2014 (IN) 5338/CHE/2014

(51) Int. Cl. G01R 31/28; G01R 31/12; G01R 31/26

(52) U.S. Cl. CPC G01R 31/2858; G01R 31/2642; G01R 31/1263

(57) ABSTRACT

A computer-implemented method for analyzing a system comprising a plurality of components is described herein according to certain aspects. The method comprises simulating the system cascading through a plurality of failures until the system fails to meet a system specification, each of the failures corresponding to a failure of one of the components. The method also comprises estimating a time to failure of the system based on a last one of the plurality of failures.

### FIELD

This application claims priority to Indian Patent Application No. 5338/CHE/2014, filed on Oct. 27, 2014, the content of which is herein incorporated by reference in its entirety.

This disclosure relates generally to electromigration, and in particular, to systems and methods for electromigration analysis.

### BACKGROUND

The phenomenal growth of mobile and wireless systems has been marked by increasing levels of integration of computational components on smaller and denser microchips. Indeed, integrated circuits may contain billions of closely-packed transistors and multi-billion copper interconnects that enable these transistors to communicate. Such aggressively downscaled components (transistors and interconnects) suffer from increasing electric fields and impurities/defects during manufacturing. Compounded by gigahertz switching, chip designers face significant challenges of reliability and design integrity, with electromigration (EM) being the foremost interconnect reliability challenge.

### SUMMARY

Certain aspects of the present disclosure provide a computer-implemented method for analyzing a system, the system comprising a plurality of components. The method comprises simulating the system cascading through a plurality of failures until the system fails to meet a system specification, each of the failures corresponding to a failure of one of the components. The method also comprises estimating a time to failure of the system based on a last one of the plurality of failures.

Certain aspects relate to an apparatus for analyzing a system, the system comprising a plurality of components. The apparatus comprises means for simulating the system cascading through a plurality of failures until the system fails to meet a system specification, each of the failures corresponding to a failure of one of the components. The system also comprises means for estimating a time to failure of the system based on a last one of the plurality of failures.

Certain aspects relate to a computer-readable medium comprising instructions stored thereon. The instructions, when executed by a processor, cause the processor to simulate the system cascading through a plurality of failures until the system fails to meet a system specification, the system comprising a plurality of components, and each of the failures corresponding to a failure of one of the components, and to estimate a time to failure of the system based on a last one of the plurality of failures.

### BRIEF DESCRIPTION OF THE DRAWINGS

FIG. 1 shows an example of a clock grid comprising buffers arranged in a redundant configuration in accordance with certain aspects of the present disclosure.

FIG. 2 shows an example of a single clock grid stage in accordance with certain aspects of the present disclosure.

FIG. 3 shows an example of a two-component system in accordance with certain aspects of the present disclosure.

FIG. 4A shows a current density profile for a failed component in accordance with certain aspects of the present disclosure.

FIG. 4B shows a current density profile for a surviving component in accordance with certain aspects of the present disclosure.

FIG. 5 is a plot illustrating the CDF evolution of a single component when the component undergoes a stress change in accordance with certain aspects of the present disclosure.

FIG. 6 is a plot comparing a CDF computed using an analytical approach according to certain aspects with a CDF computed using weakest link approximation.

FIG. 7 is a plot showing the increasing benefit of redundancy with an increase in the number of components arrange in parallel.

FIG. 8 shows an example of a 32× drive buffer with redundancies in accordance with certain aspects of the present disclosure.

FIG. 9 shows exemplary CDFs for the 32× drive buffer for varying delay degradations and a CDF for the 32× drive buffer arrived at using the weakest link approximation in accordance with certain aspects of the present disclosure.

FIG. 10 shows exemplary CDFs for a 4× drive buffer for varying delay degradations and a CDF for the 4× drive buffer arrived at using the weakest link approximation in accordance with certain aspects of the present disclosure.

FIG. 11 shows exemplary CDFs for a two-buffer redundant configuration in accordance with certain aspects of the present disclosure.

FIG. 12 shows exemplary delay degradations for a clock grid in accordance with certain aspects of the present disclosure.

FIG. 13 shows an exemplary skew-criteria based CDF for the clock grid in accordance with certain aspects of the present disclosure.

FIG. 14 is a flowchart illustrating a computer-implemented method for analyzing a system in accordance with certain aspects of the present disclosure.

FIG. 15 is a block diagram of an exemplary computer in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

Electromigration (EM) in interconnects occurs due to the movement of metal atoms, activated by momentum transfer from collisions with free electrons. When bounded by a blocking boundary such as a barrier layer, this movement causes a depletion of atoms at the cathode end and a surplus at the anode end of an interconnect. This depletion eventually leads to void nucleation and subsequent growth, resulting in failure of the interconnect. Since the critical stress for void nucleation is very small for copper dual damascene (CuDD) structures, voids can form early in the lifetime of a design.

At the individual component (metal segment, wire, etc.) level, electromigration (EM) is fairly well understood in terms of component failure (e.g., 10% resistance change) and time-to-failure (TTF) based on, for example, Black's equation. Additionally, EM recovers with a reversal in the current flow direction, and the average current may be computed using an empirical recovery factor (typically between 0.6 and 0.8). To ensure EM robustness, foundaries specify current density limits on wires.

However, there is a lack of a similar understanding at the system level. As a result, it is not known when a system fails and how component reliability stack up to cause system failure.

Conventional EM analysis treat an entire complex system as a chain (a large number of interconnects arranged in series), and applies weakest link approximation (WLA) to the system, in which the system is deemed to fail when the first component in the system fails. As a result, the conventional method for managing EM revolves around containing current densities in interconnects. These interconnects could be cell-external (e.g., signal and power networks connecting cells) or cell-internal, in which interconnects could be wires within a logic-IP (e.g., standard cell) or a mixed signal IP block.

Thus, the conventional EM analysis treats one component failure in a system as a system failure even though the system may continue to operate well after the component failure. This approach may compute a TTF that is overly pessimistic, especially for systems with redundant interconnect structures (e.g., parallel interconnects), such as clock grids, power meshes, multi-finger transistors, etc. The overly pessimistic TTF may lead a circuit designer to over design a system (e.g., widen interconnects) to meet a desired TTF, which increases the size and/or power consumption of the circuit.

Instead of the weakest link approach (which equates failure of a single interconnect with system failure), embodiments of the present disclosure analyze system failure at a higher abstraction level than failure of an individual interconnect. In this regard, embodiments of the present disclosure determine system failure when a critical system specification is violated (e.g., a predetermined change in delay, leakage, speed, clock skew, etc.).

In certain embodiments, a system (e.g., clock grid) is taken through a series of cascading EM failures (e.g., using a circuit simulator), in which each EM failure is associated with current crowding and a change in system performance. For example, each time an interconnect fails due to EM, current is redistributed among the surviving (remaining) interconnects in the system. In addition, each time an interconnect fails due to EM, the change in system performance due to the failure may be determined (e.g., using the circuit simulator). This may be done, for example, by determining system performance with the failed interconnect treated as an open circuit.

In these embodiments, system performance may be monitored as the system undergoes the EM failures discussed above. The system is deemed to fail when the system stops meeting a critical system specification (e.g., a specified delay, leakage, speed, clock skew, etc.) or the system becomes non-functional. Thus, the system is deemed to fail when the system fails to meet a critical system specification or becomes non-functional, and not when the first interconnect in the system fails due to EM. Various embodiments of the present disclosure are discussed in greater detail below.

The primary determinant for EM in an interconnect is the amount of current flowing through the interconnect. As a result, EM is a serious concern for circuits (e.g., clock network) that carry high amounts of current over a chip's lifetime. In fact, much of chip-level signal EM analysis may be focused on ensuring the safety of clock networks, even though they are physically routed at non-default widths due to delay considerations.

Pushing the performance of clock networks under the constraints of variability and skew is a significant challenge. As a result, clock networks comprising clock grids (also referred to as clock meshes) have become popular since they enable ultra-high frequency and clock signal delivery with minimal skew. Clock grids show high tolerance to variations due to their inherently high redundancy, with multiple source-to-sink paths for every sink. Thus, although the high frequency and high current characteristics of clock grids make them vulnerable to EM, their highly redundant interconnect structure breaks the WLA assumption of conventional EM containment approaches.

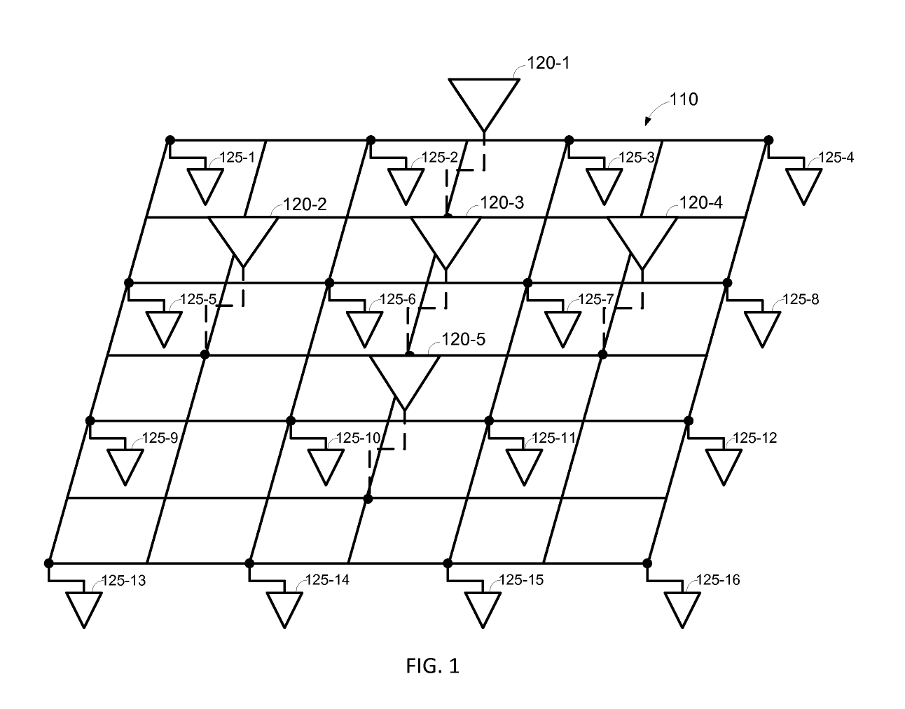

FIG. 1 shows an example of a one-level clock grid 110 comprising a plurality of interconnects (wire segments) coupled in a grid configuration. In this example, the clock grid 110 is driven by multiple buffers 120-1 to 120-5, in which the buffers 120-1 to 120-5 drive the clock grid 110 with a clock from a common clock source (not shown). The clock source may comprise a phase-locked loop (PLL) or other type of clock source. The clock grid 110 distributes the clock to a plurality of buffers 125-1 to 125-16. The input of each buffer 125-1 to 125-16 may be coupled to a respective node of the clock grid 110, and the output of each buffer 125-1 to 125-16 may drive a respective clock sink (not shown). A clock sink may comprise a flip-flop or other type of clock sink. As shown in FIG. 1, there are multiple paths from the clock source to each clock sink. Therefore, if an interconnect in one of the paths to a clock sink fails due to EM, the clock can still reach the clock sink via the remaining paths.

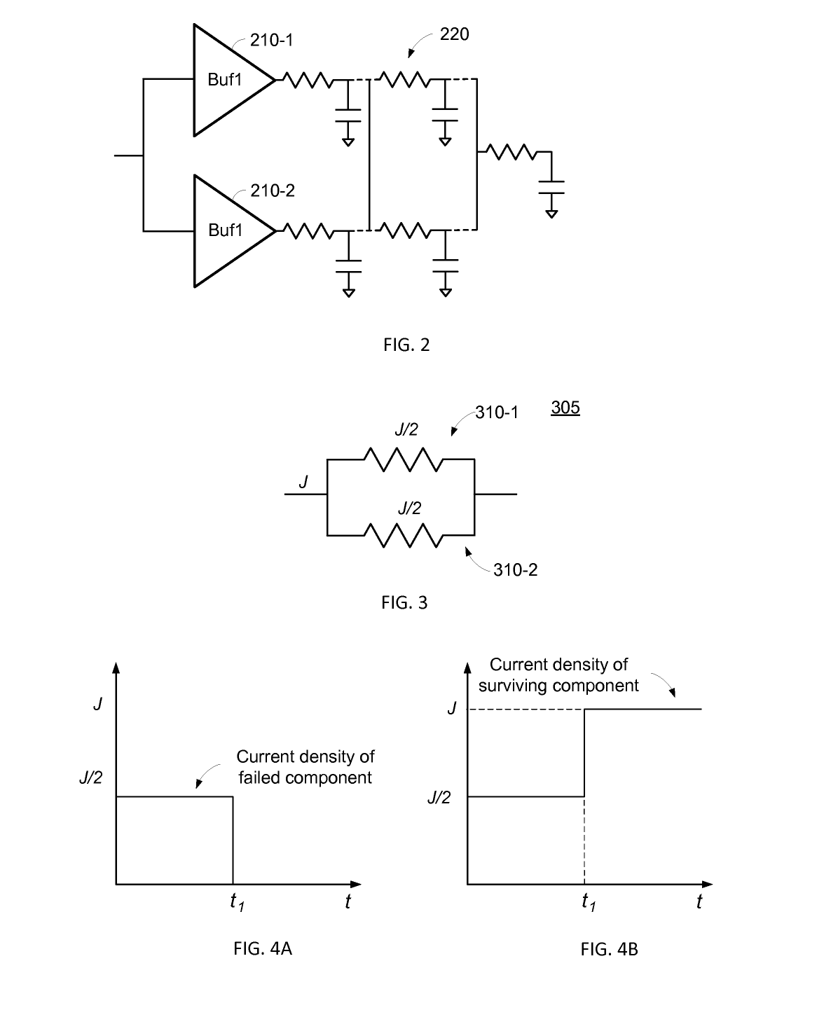

Thus, clock grids are multiply driven by multiple buffers coupled to a common clock source (an example of which is shown in FIG. 1). These redundant buffers reduce clock skew and low load/delay variations. FIG. 2 shows an exemplary schematic of a single clock grid stage, in which multiple buffers 210-1 and 210-2 drive wire segments 220. In FIG. 2, the resistances and parasitic capacitances of the wire segments are represented as resistors and capacitors, respectively.

Failures in the supply network of the clock grid may cause delay shifts. However, the supply network is also redundant due to its mesh structure and can therefore withstand some failures.

The WLA ignores all of the above redundancies and does not consider the sensitivity of system functionality to failing wires. For example, WLA ignores the possibility that a system may operate well even after a component fails. Instead of the WLA, a better criterion for system failure is based on determining when the system becomes non-functional or when a critical system specification is violated.

Accordingly, embodiments of the present disclosure analyze system failure at a higher abstraction level than an individual interconnect. In this regard, embodiments of the present disclosure determine system failure when the system becomes non-functional or when a critical system specification is violated. By analyzing system failure at a higher abstraction level, embodiments of the present disclosure take system redundancies into account in determining system failure. Circuit lifetime can be underestimated by over 2× when system redundancies are not taken into account, as in the WLA.

An analytical approach showing the benefits of using a system-level approach to determine system failure will now be described in accordance with certain aspects of the present disclosure.

EM may be computed using Black's equation, which describes EM-induced failure in a wire as follows:

t₅₀=AJ⁻ⁿe^{Q/k}^{_{B}}^{T} (1)

where t₅₀ is the time-to-failure for half of an experimental population, A is a constant depending on the material properties, J is the current density through the wire, n is a current-exponent that is empirically determined between 1 and 2, Q is the activation energy, k_{B} is the Boltzman constant, and T is the wire temperature. For bidirectional current flow in the wires, the computation can be adjusted to accommodate for partial EM recovery. In this case, the current density J (which is a temporal average) can be modified with a recovery factor, [symbol] , that is empirically obtained, as follows:

J=J_{avg}⁺− [symbol] J_{avg}⁻ (2)

where J_{avg}⁺ and J_{avg}⁻ indicate the average density in the positive and negative directions, respectively. The temperature T may incorporate the wire temperature rise ΔT, which depends on the root mean square (RMS) current density, J_{RMS}, as follows:

ΔT=cJ_{RMS}² (3)

where c is a fitting parameter. Equation (3) follows directly from heat conduction principles. Typically, a limit on the maximum temperature rise due to Joule heating is a design constraint that places limits on RMS current densities.

The EM failure statistics for each component depends on its current. For a system with redundancies, after the first component fails, current-crowding is seen in the remaining components, altering their failure statistics.

The initial failure rate, f(t), of each component is lognormal, and given as follows:

$$f ( t ) = \frac{1}{t σ \sqrt{2 π}} {e}^{\frac{- 1}{2} ( \frac{ln t - ln {t}_{50}}{σ} )} \qquad ( 4 )$$

where t₅₀ is a function of the current density of the component, as shown in equation (1). The cumulative probability distribution function (CDF) is therefore given by:

$$F ( t ) = Φ ( \frac{ln t - ln {t}_{50}}{σ} ) \qquad ( 5 )$$

where Φ(x) is the standard normal CDF. After the first component fails, the failure statistics of each surviving (remaining) component may be altered, as discussed further below with reference to FIG. 3.

FIG. 3 shows an example of a two-component system 305 comprising a first component 310-1 (e.g., wire segment) and a second component 310-2 (e.g., wire segment) coupled in parallel. The resistances of the components 310-1 and 310-2 are represented as resistors in FIG. 3. Each of the components 310-1 and 310-2 initially carries a current density, J₁, that is equal to J/2 in FIG. 3. When one of the components 310-1 and 310-2 fails at time t₁, the current density in the surviving component changes to J₂, which is equal to J in FIG. 3. This is shown in FIGS. 4A and 4B, which show the current density profiles of the failed component and surviving component, respectively. As shown in FIG. 4A, the failed component has a current density of J/2 before the failure at time t₁, and a current density of approximately zero after the failure. As shown in FIG. 4B, the surviving component has a current density of J/2 before the failure at time t₁, and a current density of J after the failure. The current density in the surviving component doubles after the failure at time t₁ since the surviving component has to carry the entire current of the system 305.

Until the first component failure at time t₁, the CDF of each component is given by:

$${F}_{1} ( t ) = Φ ( \frac{ln t - ln {t}_{50.1}}{σ} ) ) \qquad ( 6 )$$

where t_{50,1} is the mean time to failure (MTTF) for current density J₁.

After the first component failure, the current density of the surviving component becomes J₂, and the reliability of the surviving component is represent by a CDF, F₂(t), and the associated t_{50,2} for current density J₂. Therefore, the CDF trajectory of the surviving component changes from F₁ to F₂ at time t₁. To ensure continuity of the CDF curve of the surviving component after the jump in the current density, F₂ may be shifted in time by δ₁ to ensure continuity with F₁ at time t₁ such that:

F₂(t₁−δ₁)=F₁(t₁) (7).

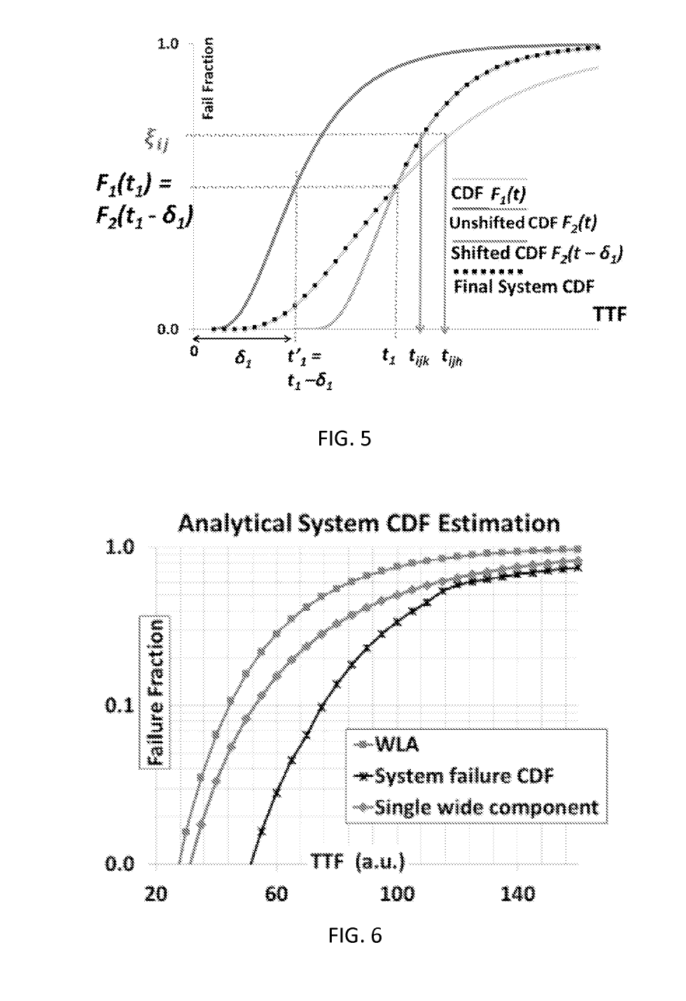

In this regard, FIG. 5 shows the CDF F₁(t) for current stress J₁, the un-shifted CDF F₂(t) for current stress J₂, and the time shifted CDF F₂(t−δ₁) for current stress J₂. As shown in FIG. 5, F₁(t) and F₂(t−δ₁) are equal at time t₁ to ensure continuity. As a result, the CDF curve for the surviving component (dotted line in FIG. 5) is given by F₁(t) before time t₁, and F₂(t−δ₁) after time t₁.

The equivalence in equation (7) physically implies that the CDF curve follows the trajectory of F₂, starting at the same fraction of the failed population under the two current stresses, but that the failure rate increases after time t₁ due to the higher current stress after time t₁. For example, for a ξᵢⱼ fail probability (y-axis in FIG. 5), the TTF changes from tᵢⱼₕ (if only the first stress were applicable) to tᵢⱼₖ (after the change of stress). The effective CDF curve is given by:

$$\begin{matrix}{F}_{1} ( t ) = Φ ( \frac{ln t - ln {t}_{50.1}}{σ} ) & 0 \leq t \leq {t}_{1} \\ {F}_{2} ( t - {δ}_{1} ) = Φ ( \frac{ln ( t - {δ}_{1} ) - ln {t}_{50.2}}{σ} ) & t \geq {t}_{1} .\end{matrix} \qquad ( 8 )$$

Note that the time shift δ₁ is derived from the continuity at time t₁. For a system where components undergo a change in stress multiple times, the above formulation can be generalized to account for k changes in current density from J₁ to J₂, J₂ to J₃, . . . , Jₖ₋₁ to Jₖ as follows:

$${δ}_{1} = {t}_{1} ( 1 - \frac{{t}_{50.2}}{{t}_{50.1}} ) \\ {δ}_{k} = ( {t}_{k} - {\sum }_{i = 1}^{k - 1} {δ}_{i} ) ( 1 - \frac{{t}_{50 , k}}{{t}_{50 , k - 1}} ) . \qquad ( 9 )$$

The above equations may be used to analyze the reliability of the system 305 in FIG. 3. In one aspect, the system 305 may be defined to be functional as long as there is one valid electrical connection between the two terminals of the system 305. If both components 310-1 and 310-2 are from the same process population, the reliability for the case when both are simultaneously functioning is given by:

R₁₁(t)=(1−F₁(t))² (10)

where F₁(t) is defined in equation (6) above.

Next, the reliability for the case when the first component fails at an arbitrary time t₁, and the second component works successfully until time t may be computed in steps. The probability of the first component failing between time t₁ and time (t₁+Δt₁) is f₁(t₁)Δt₁, where f₁(t) is the density function associated with F₁(t). After the current redistribution at time t₁, the failure statistics of the surviving component are given by the CDF F₂(t−δ₁) from equation (8). Thus, the concurrent multiplicative probability of the second component working when the first component fails is:

[1−F₂(t−δ₁)]f₁(t₁)Δt₁ (11).

Integrating over all possible failures from time 0 to t, the reliability for this case is:

R₁₂(t)=∫ₜ_{₁}₌₀^{t}^{₁}^{=t}[1−F₂(t−δ₁)]f₁(t₁)dt₁ (12).

The effective failure probability is therefore given by:

Fₚₐᵣₐₗₗₑₗ(t)=[R₁₁(t)−2R₁₂(t)] (13).

The above equations enable the EM reliability of components connected in parallel to be compared with a single narrow or wide component. In this regard, for a given CDF for a single component, FIG. 6 compares the CDF for the two-component system arrived at using the above analytical approach with the WLA. More particularly, FIG. 6 shows the CDF for the two-component system arrived at using the analytical approach discussed, the CDF for a single narrow component, and the CDF of a single wide component. Note that for a single narrow component case or single wide component case, the WLA is rightly applicable. However, the conventional approach even applies the WLA to a parallel system. It is clear from FIG. 6 that the conventional approach leads to pessimistic estimates of failure times by comparing the CDF for the two-component system arrived at using the above analytical approach with the WLA for the single narrow component. For an exemplary failure fraction of 10%, the TTF is computed to be 35% lower. Thus, the WLA could lead to overdesign as designers strive to fix failures that will not happen.

An alternative to the two-component system in FIG. 3 is to use a single component of twice the width to carry the entire current. Such a component has the same current density as the parallel components in FIG. 3, and its failure probability is the single wide component CDF in FIG. 6. However, as shown in FIG. 6, the failure probability for the single wide component is significantly worse than the two-component system. Qualitatively, this margin arises from EM stochasticity, since the probability of two narrow components failing simultaneously is smaller than that of a single wide component failing.

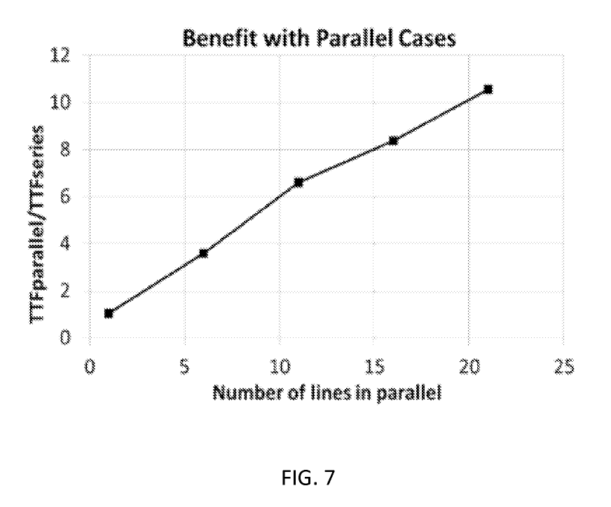

Further, such a benefit from redundancy scales with the extent of parallelism, as illustrated in FIG. 7. Typically in input/output buffers and chip level power/ground networks, the wires are often required to be wide (>1 μm) to support carrying large currents. Such wires can be laid out as a single wide structure (within the maximum width constraint by foundry), or as a parallel connection of several narrow components, wherein the narrow components adhere to the minimum design rule constraint (DRC) spacing specified by the foundry.

FIG. 7 plots the ratio of the TTF for a structure with parallel narrow wires over the TTF for a single wide wire, in which the width of the single wide wire matches the sum of the widths of the narrow wires. This means that the wire parasitics for both cases are roughly the same, but the set of narrow wires occupies a larger area due to the DRC spacing constraints. The structure with the parallel narrow wires is assumed to fail when all of the wires fail. FIG. 7 plots the ratio of the TTF for the parallel narrow wires over the TTF for the single wide wire as a function of the number of parallel wires. As can be seen in FIG. 7, the benefit from redundancy monotonically increases as the number of parallel wires increases.

The analytical two-component example given above is a useful illustration. However, complex circuits may not admit analytical solutions and the failure criteria may involve more complicated metrics. In this regard, the EM stochasticity may be numerically modeled using a Monte Carlo (MC) analysis. In certain aspects, each MC trail may model a cascade of EM events to successively degraded states. In each trail, a TTF sample is generated for each component, based on component failure CDFs. Starting from the lowest TTF, each iteration in a trail includes the next lowest TTF. An EM event on a component is modeled by catastrophic increase in its resistance, essentially an open circuit. Consequently, every EM failure causes:
(1) Current crowding—which changes the wire failure CDFs and also causes additional Joule heating in the surviving components; and
(2) Changes in circuit performance (e.g., delay) due to the EM failures, which could impact clock grid metrics such as skew.
   Moreover, while some EM events may result in functional failure, others may result in only a small performance change due to redundancies in the circuit.

Both of the above effects of an EM failure may be incorporated into the MC analysis. The effect of current crowding is well understood using the analysis discussed above for changes in current stress. As discussed above, the component failure CDF is an un-shifted lognormal before the first component failure. After the first component failure, the CDF may be modified using equations (8) and (9). The effect of circuit performance change in each iteration may be computed by conducting a SPICE-based delay analysis for the example in which the system performance being monitored is circuit delay.

The iterations in an MC trail may stop when the cumulative impact of the EM failures causes the circuit delay to violate a specification of the circuit (e.g., 10% delay degradation). The corresponding time instant becomes the TTF of the circuit. Note that depending on the circuit functionality and layout, multiple component failures may be required to reach circuit failure. Eventually, a large number of such trails may be conducted (which depends on the desired confidence level for estimation-error to be lower than specified) to obtain the circuit CDF. In certain aspects, the number of MC trails may be kept to a limit of 100.

The final exemplary algorithm according to certain aspects may be summarized as below:
Input: Original SPICE netlist of the circuit-under-test (CUT), testbench for current, delay measurement; random number generator

Output: CDF of the circuit (probabilistic TTF)
Variable: mcᵢ (number of Monte Carlo trails)
1. Set mcₗᵢₘᵢₜ based on desired accuracy
2. For (mcᵢ=0; mcᵢ++;mcᵢ < mcₗᵢₘᵢₜ) {
3. t=0, SPICE simulation of CUT → currents through all resistors
4. use random number generator to assign TTF to all resistors
5. rank order the resistors in a TTF manner; EM event on resistor
with least TTF
6. while (circuit-delay degradation < specification) {
7. recalculate the new current flow in the resistors
8. TTF-rank order resistors; EM event on resistor with least TTF
9. }
10. report circuit TTF
11. }
12. rank order various TTF to generate circuit CDF

In the above exemplary algorithm, the number of MC trails that are conducted is mcₗᵢₘᵢₜ, in which a circuit TTF is computed for each MC trail. The TTFs computed from the MC trails are used to generate the CDF (probabilistic TTF) for the circuit.

In each MC trail, the initial current through each resistor is computed in step 3 (i.e., current at time t=0 is computed in step 3). It may be assumed that all of the resistors are functional at time t=0. Each resistor may model a wire (e.g., interconnect in the circuit), which has resistance. A TTF is then randomly assigned to each resistor in step 4. To do this, the random number generator may randomly assign a failure probability to each resistor between zero and one. For each resistor, the respective TTF may be calculated by setting the CDF for the resistor equal to the failure probability assigned to the resistor, and solving for time t to obtain the TTF. Initially, the CDF of each resistor may given by equation (5), in which t₅₀ is a function of the current flowing through the resistor, as shown in equation (1).

After the TTFs are determined, the lowest one of the TTFs (i.e., least TTF) is determined in step 5. The first EM event is deemed to occur at the resistor with the least TTF at time t equal to the least TTF. In other words, the resistor with the least TTF is deemed to be the first component to fail due to EM. After the first EM failure, the resulting change in the circuit delay may be determined in step 6. This may be done, for example, by determining the circuit delay with the failed resistor treated as an open circuit. If the circuit delay fails to meet the system specification after the first EM failure, then the system is deemed to fail. In this case, system failure occurs at the first EM failure. However, due to system redundancy, this will likely not be the case.

If the circuit delay meets the system specification after the first EM failure, then the currents in the surviving (remaining) resistors are recalculated in step 7. This may be done, for example, by calculating the currents in the surviving resistors with the failed resistor treated as an open circuit. The TTFs for the surviving resistors may then be updated to account for the changes in the currents of the surviving resistors according to equations (8) and (9). More particularly, for each surviving resistor, the respective TTF may be updated by: updating the CDF for the resistor according to equations (8) and (9), setting the updated CDF for the resistor equal to the failure probability assigned to the resistor, and solving for time t to obtain the TTF. Note that the CDF for each resistor is updated by determining the CDF for the resistor based on t_{50,2} (which is a function of the new current for the resistor) and time shifting the CDF by the time shift according to equation (9). After the TTFs are updated for the surviving resistors, the lowest one of the TTFs (least TTF) among the surviving resistors from the first EM event may be determined. The second EM event is deemed to occur at the resistor with the least TTF among the surviving resistors from the first EM event. Also, the second EM event is deemed to occur at time t equal to the least TTF among the surviving resistors from the first EM event. After the second EM failure, the change in the circuit delay may be determined This may be done, for example, by determining the circuit delay with the two failed resistors (i.e., resistors corresponding to the first and second EM failures) treated as open circuits. If the circuit delay fails to meet the system specification after the second EM failure, then the system is deemed to fail.

If the circuit delay meets the system specification after the second EM failure, then steps 7 and 8 may be repeated for the surviving resistors. Steps 7 and 8 may be repeated until the circuit delay fails to meet the system specification (i.e., steps 7 and 8 may be repeated until the condition of the while loop is no longer met). When the circuit delay fails to meet the system specification, the circuit TTF for the respective MC trail may correspond to the least TTF in the last iteration of the MC trail (i.e., the least TTF in the final repetition of steps 7 and 8). As discussed above, the TTFs from the MC trails (e.g., 100 MC trails) may be used to generate the CDF (probabilistic TTF) for the circuit.

A WLA analysis for the circuit may also be conducted using the above MC algorithm by assuming that the first component failure causes the circuit to fail regardless of whether the circuit performance still meets the system specification. It is clear that the WLA-based TTF for each MC trail is the least TTF corresponding to the first EM event. Thus, the CDF of the circuit for the WLA case can be generated from the WLA-based TTFs from the MC trails.

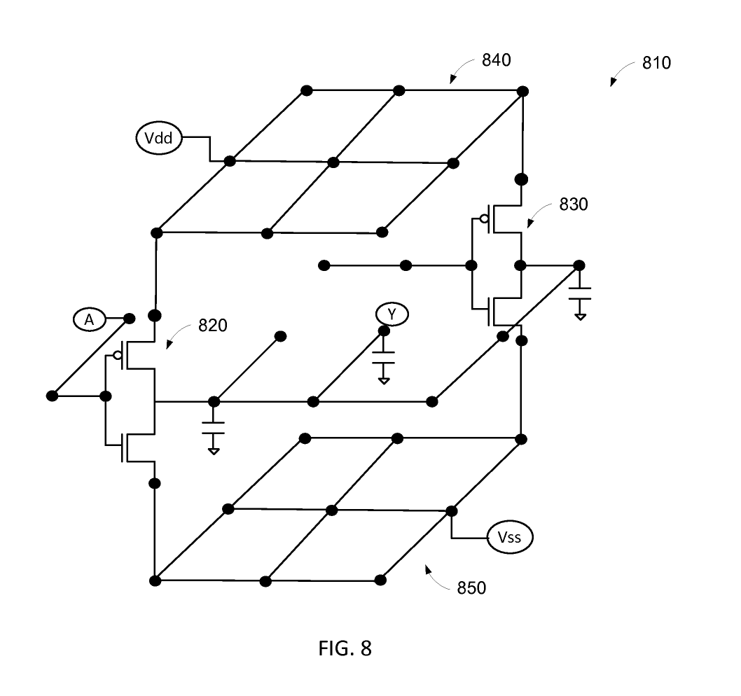

The above MC analysis may be applied to systems with redundancies to more accurately model the CDF of these systems. For example, the MC analysis may be applied to a single 28 nm 32× drive buffer 810 shown in FIG. 8. The drive buffer 810 may drive a lumped load at a frequency of 1 GHz, and may be taken from an industry cell library. As shown in FIG. 8, the driver buffer 810 comprises redundant drivers 820 and 830 in the signal path of the drive buffer 810. FIG. 8 also shows the power supply, Vdd and Vss, for the drive buffer, which are connected to the redundant drivers 820 and 830 by power meshes 840 and 850. In this example, the candidate EM sites for the MC analysis include the resistors (wire segments) in the power meshes 840 and 850, and the resistors (wire segments) in the signal path of the drive buffer 810.

Note that the redundancies in the drive buffer 810 arise from: (a) parallel M1-M2 lines connected to the supply, so that an EM event in one metal level may still allow the drive buffer to remain functional, and (b) failure in the output line can result in a lowering of the cell power (e.g., from 32× to 30×), which alters the delay but maintains functionality.

It should be noted that the cell-internal segments (on M1/M2) may be much smaller in length, and the Blech length benefit is typically not applicable as these segments carry purely AC current.

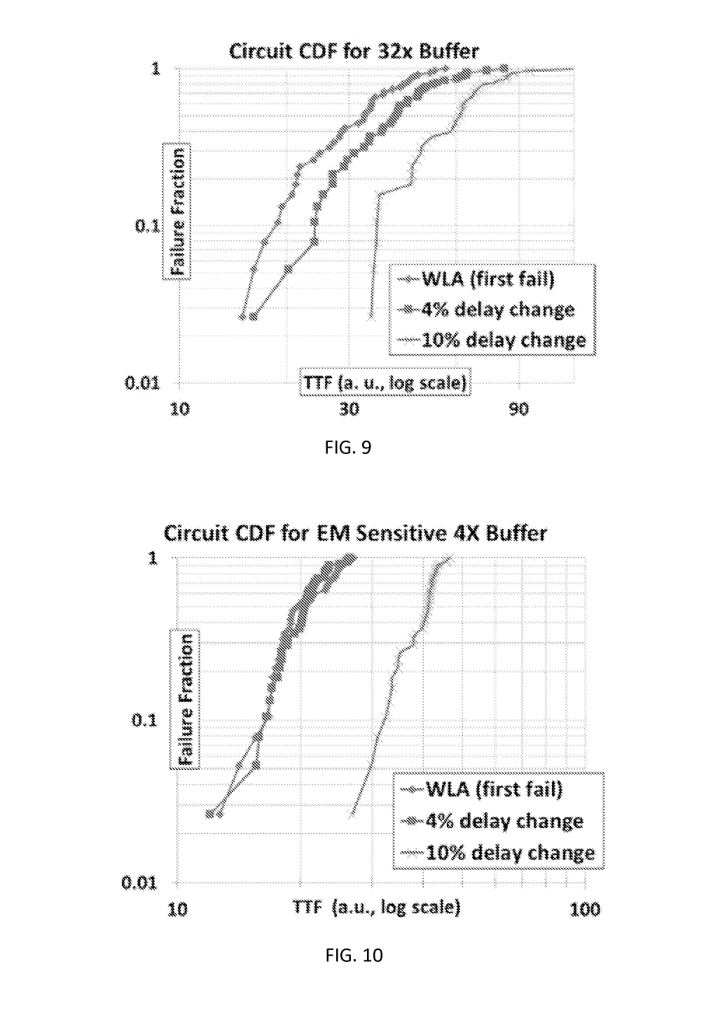

Using the above MC analysis according to certain aspects, the circuit failure CDFs for the 32× drive buffer shown in FIG. 9 are obtained. More particularly, FIG. 9 shows failure CDFs for the 32× drive buffer for varying extents of acceptable delay degradations (e.g., 4% and 10% delay degradations). Also shown in FIG. 9 is the failure CDF for the WLA case (i.e., circuit failure at first EM event). In this example, a relaxed specification implies acceptability of several EM events in the buffer. For a 10% fail fraction, the benefit from the inherent circuit redundancies is apparent in the form of a 2× margin in the TTF over the WLA.

FIG. 10 shows the above MC analysis applied to a 4× drive buffer driving a correspondingly lowered target load at a frequency of 1 GHz. Since the 4× buffer has fewer redundancies, and corresponding lower margins due to tighter layout, the failure CDFs for the 4% and 10% delay degradations are closer to the WLA.

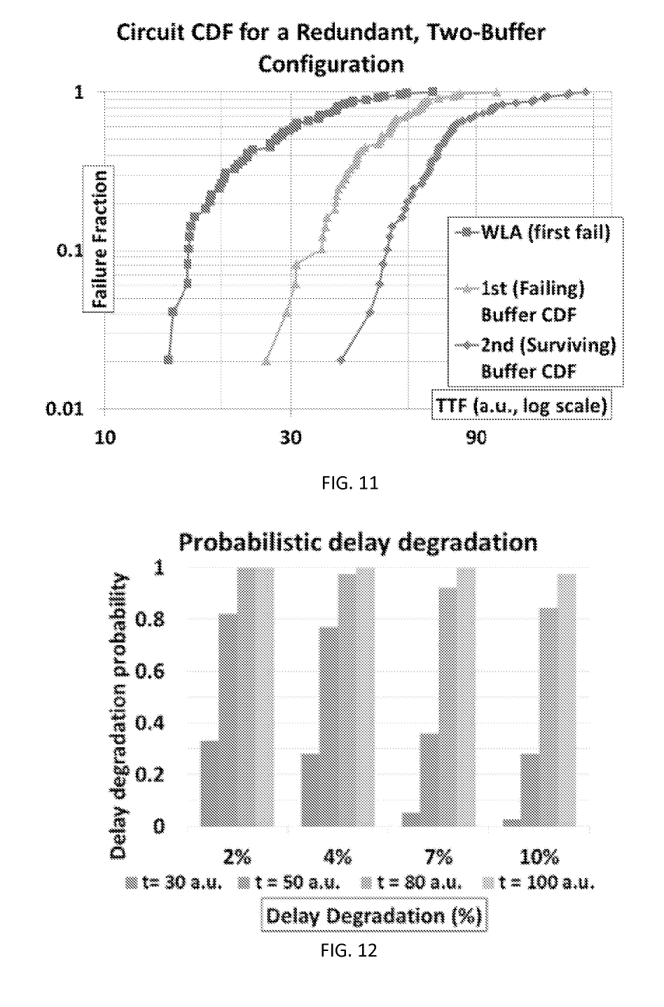

The failure evolution for the case when two high-drive buffers are arranged in a redundant configuration will now be discussed according to certain aspects. In this case, the WLA predicts complete system failure as soon as the first metal fails. In reality, a delay degradation in a single buffer due to a metal failure does not necessarily mean system failure when several buffers are arranged in a redundant configuration (several buffers are in parallel). Indeed, if a buffer delay increases, its switching burden is placed on the other buffer, thereby moderating the impact. In FIG. 2, for example, if the first buffer 210-1 degrades, then the second buffer 210-2 compensates for it. FIG. 11 shows the CDF for an individual buffer and the CDF for a system with two buffers arrange in a redundant configuration. FIG. 11 also shows the CDF for the WLA. As can be seen in FIG. 11, the system continues to work even after the first resistor (metal) fails or after the first buffer fails entirely. A significant margin is shown between the TTF of the system and the failure of the first buffer. The margin increases with the addition of more redundant buffers. Note that for this analysis, the failure criterion is the degradation in the slack.

The above MC analysis may be applied to a clock grid structure in accordance with certain aspects. In the clock grid, redundancies lie within the cells, in the power grid (mesh), and in the clock grid itself, which is driven by multiple buffers. In one example, the one-level clock grid shown in FIG. 1 may be analyzed, with an exemplary buffer and its four identical neighbors to the north, south, east and west (e.g., buffers 120-1 to 120-5), implemented with 28 nm cell libraries at a frequency of 1 GHz. In this example, wire widths in the clock grid may be large so that the likelihood of EM failure is negligible and the analysis may focus on EM failures that may occur in within-cell wires or in the power grid (an example of which is shown in FIG. 8).

A primary figure of merit for a clock grid is the skew, or difference in arrival times at sink nodes in the grid. For the above clock grid, the skew criterion can be translated to a delay criterion, and the allowable degradation of the buffer and its neighbors constrained. A set of ways in which the skew specification can be met even after the buffers degrade are as follows:
1) When all of the five neighboring buffers degrade by less than 2%;
2) When all of the five neighboring buffers degrade in a similar, bounded manner (e.g., between 2%-4%, 4%-7%, or 7%-10%); and
3) When a buffer degrades by over 10% and all of its neighbors degrade by no more than 2%, or when a buffer and one of its neighbors degrade by over 7% and the other buffers degrade by less than 4%.
   The above list is not an exhaustive list of all cases where the system operates correctly. Thus, failure analysis based on these criteria is pessimistic.

FIG. 12 shows the probabilistic delay degradation CDFs of individual buffers (an example of which is shown in FIG. 8) with time. This data from the individual buffer enables the failure probability of the clock grid to be estimated at any given time with any given failure criteria (say x % delay degradation).

Consequently, the above relations can be used to arrive at the failure probabilities for the individual cases enumerated above, and therefore for the effective skew-failure probability as follows:

P₁: (1−F_{2%})⁵

P₂: (F_{2%}−F_{4%})⁵+(F_{4%}−F_{7%})⁵+(F_{7%}−F_{10%})⁵

P₃: ⁵C₂(1−F_{4%})³(F_{7%}−F_{10%})²+(F_{7%}−F_{10%})⁵+⁵C₁(1−F_{2%})²F_{10%}

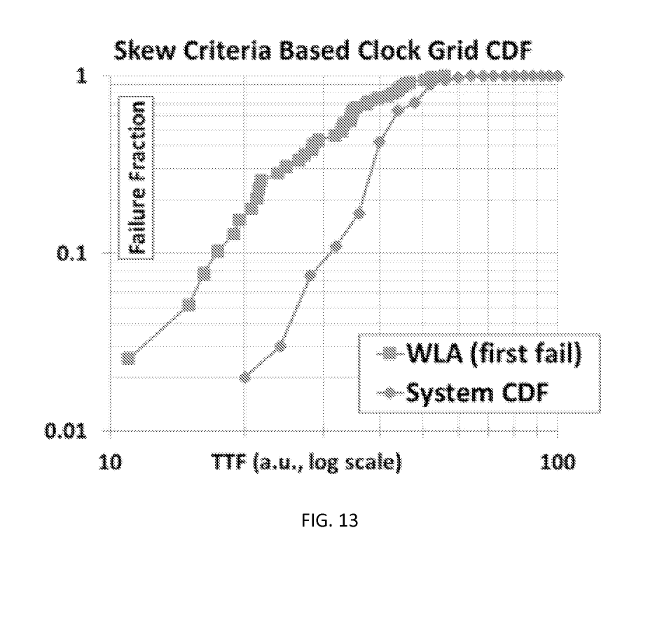

F_{skew}=1−(P₁+P₂+P₃) (14)

where F_{x%} represents the CDF of each buffer, representing the probability that the delay degradation is more than x %, and P₁ to P₃ are pass-probabilities for the above cases. FIG. 13 shows the CDF for the clock grid based on the above skew-criteria. As shown in FIG. 13, for a 10% failure fraction, there is about a 2× margin between the WLA and the skew-criteria based failures.

In this case, the benefit from system redundancies (in the form of multiple buffers) is apparent, as the WLA turns out to be significantly pessimistic. As shown in FIG. 13, aspects of the present disclosure result in over a 2× margin in TTF, wherein system failure is attributed in a more accurate manner to the skew. Such a margin can be further improved by accurately incorporating the arrival times at each sink node, along with the logical correlation.

Although aspects of the present disclosure are described using the example of EM failure, it is to be appreciated that the present disclosure is not limited this example, and may be applied to other types of failure mechanisms such as inter-layer dielectric breakdown, transistor failure, etc. The other types of failure mechanisms may also be stochastic, and therefore have similar statistical properties as EM failure. In general, the time to failure of a system may be determined according to aspects of the present disclosure by simulating the system cascading through a series of failures until the system fails to meet a system specification (e.g., delay degradation, clock skew, etc.).

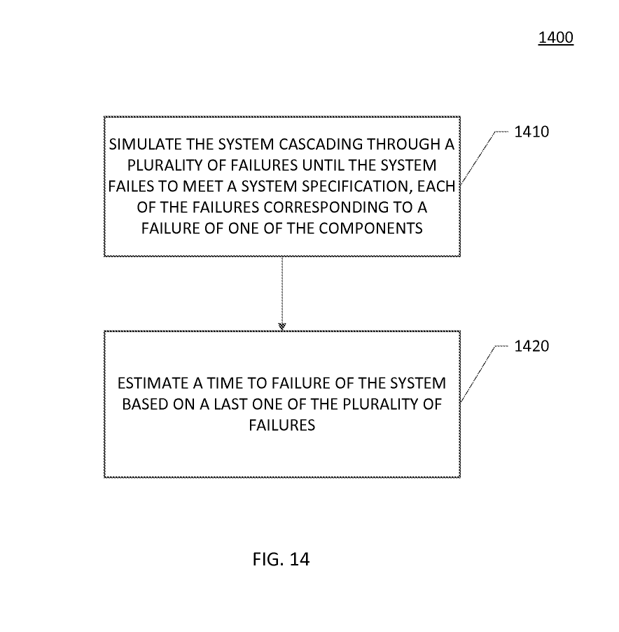

FIG. 14 is a flowchart illustrating a computer-implemented method 1400 for analyzing a system with redundancies according to certain aspects of the present disclosure. The system comprises a plurality of components, in which the components may comprise metal wires arranged in a grid (e.g., power grid, clock grid, etc.) and/or a plurality of buffers (e.g., buffers 120-1 to 120-5) arranged in parallel.

In step 1410, the system is simulated cascading through a plurality of failures until the system fails to meet a system specification, each of the failures corresponding to a failure of one of the components. Each of the failures may comprise an electromigration (EM) failure, an inter-layer dielectric breakdown, a transistor failure, etc. Each of the failures may involve changes in the current distribution among the surviving components, and changes in system performance. The system specification may comprise a delay (e.g., x % delay degradation), skew, and/or other specification.

In step 1420, a time to failure of the system is estimated based on a last one of the plurality of failures. For example, the time to failure may correspond to the last failure, which causes system performance to degrade to the point where the system fails to meet (violates) the system specification.

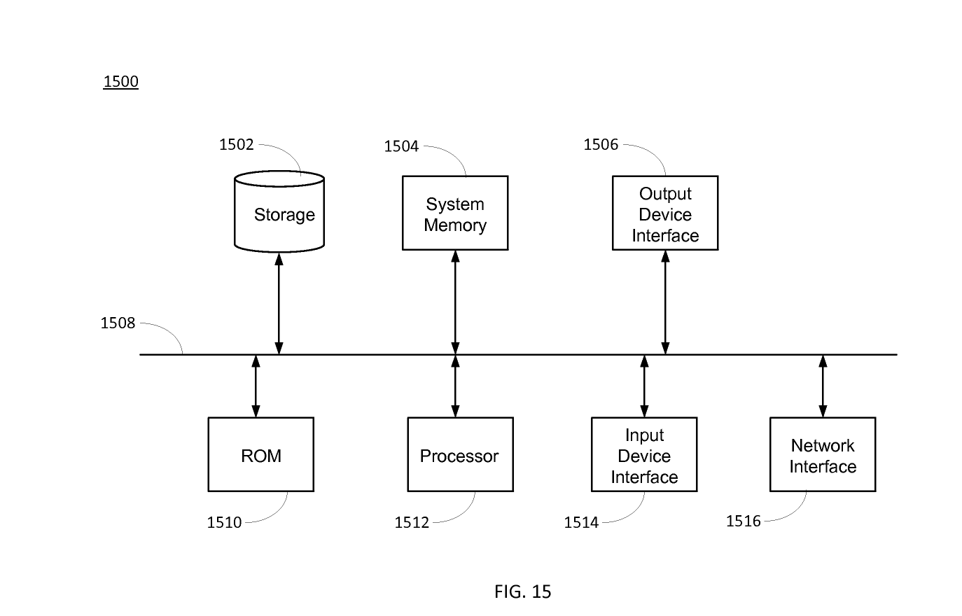

Step 1410 may be performed by a computer, an example of which is described below with reference to FIG. 15. In this example, the computer may simulate the first component failure in the system by determining failure statistics for each of the plurality of components (e.g., based on equation (5) discussed above), and using the failure statistics to determine a time to failure of the first component to fail.

After the component failure, the computer may simulate the next component failure in the system by updating the failure statistics for each of the surviving components (e.g., based equation (8) discussed above), and using the updated statistics to determine a time to failure of the next component to fail. The computer may repeat the above steps until the system fails to meet a system specification.

In regard, after each simulated component failure, the computer system may simulate performance of the system (e.g., with the failed components treated as an open circuit), and determine whether the simulated performance (e.g., delay, clock skew, etc.) meets the system specification. If the simulated performance still meets the system specification, then the computer may simulate the next component failure as discussed above. If not, then the computer may end the simulation, and determine a time to failure of the system based on the time to failure of the last component to fail in the simulation.

FIG. 15 illustrates a computer 1500 with which aspects of the present disclosure may be implemented. The computer 1500 may include a bus 1508, a processor 1512, a system memory 1504, a read-only memory (ROM) 1510, a permanent storage device 1502, an input device interface 1514, an output device interface 1506, and a network interface 1516.

The bus 1508 collectively represents all system, peripheral, and chipset buses that communicatively connect the numerous internal devices of the computer 1500. For instance, the bus 1508 communicatively connects the processor 1512 with the ROM 1510, the system memory 1504, and the permanent storage device 1502.

From these various memory units, the processor 1512 may retrieve instructions (e.g., code) that, when executed by the processor 1515, cause the processor to perform processes according to any aspects of the present disclosure discussed above. For example, the instructions may cause the processor 1512 to perform the system-level failure analysis according to any aspects of the present disclosure discussed above. The processor 1512 can be a single processor or a multi-core processor in different implementations.

The ROM 1510 stores static data and instructions that are needed by the processor 1512 and other modules of the system. Permanent storage device 1502 may comprise one or more non-volatile memory devices that store instructions and data even when the computer 1500 is off Some implementations of the present disclosure may use a mass-storage device (such as a magnetic or optical disk and its corresponding disk drive) as the permanent storage device 1502. Other implementations may use a removable storage device (such as a floppy disk, flash drive, and its corresponding disk drive) as the permanent storage device 1502. The system memory 1504 may comprise a volatile read-and-write memory device, such a random access memory. The system memory 1504 may store some of the instructions and data that the processor needs at runtime.

The bus 1508 also connects to input and output device interfaces 1514 and 1506. The input device interface 1514 enables a user to communicate information to the system. Input devices that may be used with the input device interface 1514 include, for example, alphanumeric keyboards and pointing devices (also called “cursor control devices”). The output device interfaces 1506 enables, for example, the display of images generated by the computer 1500. Output devices that may be used with the output device interface 1506 include, for example, printers and display devices, such as cathode ray tubes (CRT) or liquid crystal displays (LCD).

Finally, as shown in FIG. 15, the bus 1508 also couples computer 1500 to a network through the network interface 1516. In this manner, the computer 1500 can be a part of a network of computers (such as a local area network (“LAN”), a wide area network (“WAN”), or an Intranet, or a network of networks, such as the Internet. Any or all components of computer 1500 can be used in conjunction with the subject disclosure.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read only memory (ROM), flash memory, EPROM memory, EEPROM memory, registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the wireless node, all which may be accessed by the processor through the bus interface. Alternatively, or in addition, the machine-readable media, or any portion thereof, may be integrated into the processor, such as the case may be with cache and/or general register files.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC (Application Specific Integrated Circuit) with the processor, the bus interface, the user interface in the case of an access terminal), supporting circuitry, and at least a portion of the machine-readable media integrated into a single chip, or with one or more FPGAs (Field Programmable Gate Arrays), PLDs (Programmable Logic Devices), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk, and Blu-ray® disc where disks usually reproduce data magnetically, while discs reproduce data optically with lasers. Thus, in some aspects computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented herein. For example, such a computer program product may comprise a computer-readable medium having instructions stored (and/or encoded) thereon, the instructions being executable by one or more processors to perform the operations described herein. For certain aspects, the computer program product may include packaging material.

Further, it should be appreciated that modules and/or other appropriate means for performing the methods and techniques described herein can be downloaded and/or otherwise obtained by an access terminal and/or base station as applicable. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that an access terminal and/or base station can obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A computer-implemented method for analyzing a system, the system comprising a plurality of components, the method comprising:
simulating the system cascading through a plurality of failures until the system fails to meet a system specification, each of the failures corresponding to a failure of one of the components; and
estimating a time to failure of the system based on a last one of the plurality of failures.

2. The method of claim 1, wherein each failure comprises an electromigration (EM) failure, an inter-layer dielectric breakdown, or a transistor failure.

3. The method of claim 1, wherein the components comprise a plurality of metal leads coupled in a grid.

4. The method of claim 3, wherein the grid comprises at least one of a power grid or a clock grid.

5. The method of claim 1, wherein the components comprise a plurality of buffers coupled in parallel.

6. The method of claim 5, wherein the plurality of buffers drive a clock grid.

7. The method of claim 1, wherein the system specification comprises a delay, or a skew.

8. The method of claim 1, further comprising:
for each of at least one of the failures, performing the steps of:
determining a change in current distribution in the system caused by the failure;
determining failure statistics for each of the components still functioning after the failure based on the change in the current distribution; and
determining a time to failure for a next one of the failures based on the determined failure statistics.

9. The method of claim 8, wherein determining the failure statistics for each of the components still functioning after the failure further comprises:
determining a cumulative probability distribution function (CDF) for the component based on current in the component after the failure; and
time shifting the CDF for the component based on a time of the failure.

10. The method of claim 8, wherein determining the change in the current distribution in the system caused by the failure further comprises treating the component corresponding to the failure as an open circuit.

11. An apparatus for analyzing a system, the system comprising a plurality of components, the apparatus comprising:
means for simulating the system cascading through a plurality of failures until the system fails to meet a system specification, each of the failures corresponding to a failure of one of the components; and
means for estimating a time to failure of the system based on a last one of the plurality of failures.

12. The apparatus of claim 11, wherein each failure comprises an electromigration (EM) failure, an inter-layer dielectric breakdown, or a transistor failure.

13. The apparatus of claim 11, wherein the components comprise a plurality of metal leads coupled in a grid.

14. The apparatus of claim 13, wherein the grid comprises at least one of a power grid or a clock grid.

15. The apparatus of claim 11, wherein the components comprise a plurality of buffers coupled in parallel.

16. The apparatus of claim 15, wherein the plurality of buffers drive a clock grid.

17. The apparatus of claim 11, wherein the system specification comprises a delay, or a skew.

18. The apparatus of claim 11, wherein, for each of at least one of the failures, the apparatus comprises:
means for determining a change in current distribution in the system caused by the failure;
means for determining failure statistics for each of the components still functioning after the failure based on the change in the current distribution; and
means for determining a time to failure for a next one of the failures based on the determined failure statistics.

19. The apparatus of claim 18, wherein the means for determining the failure statistics for each of the components still functioning after the failure further comprises:
means for determining a cumulative probability distribution function (CDF) for the component based on current in the component after the failure; and
means for time shifting the CDF for the component based on a time of the failure.

20. The apparatus of claim 18, wherein the means for determining the change in the current distribution in the system caused by the failure further comprises means for treating the component corresponding to the failure as an open circuit.

21. A computer-readable medium comprising instructions stored thereon that, when executed by a processor, cause the processor to:
simulate the system cascading through a plurality of failures until the system fails to meet a system specification, the system comprising a plurality of components, and each of the failures corresponding to a failure of one of the components; and
estimate a time to failure of the system based on a last one of the plurality of failures.

22. The computer-readable medium of claim 21, wherein each failure comprises an electromigration (EM) failure, an inter-layer dielectric breakdown, or a transistor failure.

23. The computer-readable medium of claim 21, wherein the components comprise a plurality of metal leads coupled in a grid.

24. The computer-readable medium of claim 23, wherein the grid comprises at least one of a power grid or a clock grid.

25. The computer-readable medium of claim 21, wherein the components comprise a plurality of buffers coupled in parallel.

26. The computer-readable medium of claim 25, wherein the plurality of buffers drive a clock grid.

27. The computer-readable medium of claim 21, wherein the system specification comprises a delay, or a skew.

28. The computer-readable medium of claim 21, wherein, for each of at least one of the failures, the computer-readable medium further comprises instructions for causing the processor to:
determine a change in current distribution in the system caused by the failure;
determine failure statistics for each of the components still functioning after the failure based on the change in the current distribution; and
determine a time to failure for a next one of the failures based on the determined failure statistics.

29. The computer-readable medium of claim 28, wherein the instructions for causing the processor to determine the failure statistics for each of the components still functioning after the failure further comprises instructions for causing the processor to:
determine a cumulative probability distribution function (CDF) for the component based on current in the component after the failure; and
time shift the CDF for the component based on a time of the failure.

30. The computer-readable medium of claim 28, wherein the instructions for causing the processor to determine the change in the current distribution in the system caused by the failure further comprises instructions for causing the processor to treat the component corresponding to the failure as an open circuit.
